(19) United States
(12) Patent Application Publication
(10) Pub. No.: US 2026/0249528 A1
(43) Pub. Date: Aug. 27, 2026

(54) RESIN MOLDED ARTICLE WITH COATING FILM, METHOD FOR MANUFACTURING THE SAME, AND OPTICAL DEVICE

(71) Applicants: Panasonic Automotive Systems Co., Ltd., Yokohama-shi (JP); Panasonic Holdings Corporation, Osaka (JP)

(72) Inventors: Shouma NISHINO, Osaka (JP); Toki HIGA, Osaka (JP); Masaru FUJITA, Osaka (JP); Takayuki NAGAHARA, Osaka (JP); Hiroki GAMO, Osaka (JP); Takashi MORIMOTO, Osaka (JP); Hiroshi MORIOKA, Osaka (JP); Kazuhiko KANEUCHI, Osaka (JP)

(21) Appl. No.: 19/529,683

(22) Filed: Feb. 4, 2026

(30) Foreign Application Priority Data
Feb. 21, 2025 (JP) 2025-027237
Mar. 27, 2025 (JP) 2025-054201

(51) Int. Cl. B29C 45/14; B29C 33/42; B29C 45/16

(52) U.S. Cl. CPC B29C 45/1418; B29C 33/424; B29C 45/14065; B29C 45/14262; B29C 45/14467; B29C 45/1671

(57) ABSTRACT

A resin molded article with a coating film, includes: a primary resin molded component having a through-hole; and an optically transparent coating film covering one end surface of the through-hole of the primary resin molded component and a front surface of the primary resin molded component around the one end surface of the through-hole.

### CROSS REFERENCE TO RELATED APPLICATION

This application claims priorities of Japanese Patent Application No. 2025-27237 filed on February 21, 2025 and Japanese Patent Application No. 2025-54201 filed on March 27, 2025, the contents of which are incorporated herein by reference.

### BACKGROUND OF THE INVENTION

### 1. Field of the Invention

The present disclosure relates to a resin molded article with a coating film, a method for manufacturing the same, and an optical device using the resin molded article with a coating film.

### 2. Description of the Related Art

In recent years, in an interface such as a display or a switch, there has been a demand for a decorative component that has a high-quality decorative surface and, for example, can be given a tactile sensation to the surface in combination with the texture of wood or various designs when the illumination or the display is turned off, and is capable of high-definition optical display when the illumination or the display disposed on the back surface of the decorative component is turned on. In addition, there has been a demand for a decorative component having a concealing property that a symbol mark or the display disposed on the back surface of the decorative component cannot be seen through when the illumination or the display is not used (off).

Examples of the optical device such as the display and the switch include a display and a switch obtained by insert-molding a decorative film on the front surface or the back surface of a resin molded article. When a decorative film is used on the surface of a resin molded article, even if high-definition grain is provided on the protective layer or the hard coat layer on the film surface, the grain is likely to be crushed during insert-molding. On the other hand, even in a method of transferring the grain formed on the surface of a mold for insert-molding to the surface of the protective layer or the hard coat layer of the decorative film, it is difficult to form a high-definition grain shape on the surface of the protective layer or the hard coat layer having poor fluidity, and thus it is difficult to realize a sufficient tactile sensation.

On the other hand, when the decorative film is used on the back surface of the resin molded article, the light is likely to be diffused until the light reaches from the back surface to the front surface of the resin molded article, and display blurring may occur. Furthermore, in a case where grain is formed on the surface of the resin molded article by using a mold, it is difficult to transfer a fine uneven grain shape with high accuracy in that light is likely to further diffuse, due to the influence of the grain, to deteriorate display blurring, that insufficient surface hardness of the resin is likely to cause the surface to be damaged, and that the resin to be molded has a poor fluidity. In addition, in any of the above methods of production, cost increase is a problem because the methods each use a decorative film.

### SUMMARY

The present disclosure is intended to solve the above-mentioned problems, and one non-limiting and exemplary embodiments provides a resin molded article with a coating film having high decoration quality, capable of high-definition optical display when used in an optical device, and on the other hand, having a concealing property that a symbol or the like cannot be seen through other than during use.

In one general aspect, the techniques disclosed here feature: a resin molded article with a coating film, includes:

a primary resin molded component having a through-hole; and

an optically transparent coating film covering one end surface of the through-hole of the primary resin molded component and a front surface of the primary resin molded component around the one end surface of the through-hole.

In another general aspect, the techniques disclosed here feature: an optical device, includes:

the resin molded article with a coating film according to claim 1;

a shielding portion covering a circumference of another end surface of the through-hole and forming a dark room with a back surface of the resin molded article; and

a light irradiation unit configured to irradiate from inside the dark room formed between the back surface of the resin molded article and the shielding portion to another end surface of the through-hole with light.

In further general aspect, the techniques disclosed here feature: a method for manufacturing a resin molded article with a coating film, the method includes:

preparing a primary resin molded component having a through-hole; and

covering one end surface of the through-hole of the primary resin molded component and a front surface of the primary resin molded component around the one end surface of the through-hole with an optically transparent coating film to obtain a resin molded article with a coating film including the primary resin molded component and the coating film.

The resin molded article with a coating film according to the present disclosure has a high decoration quality and is capable of high-definition optical display when used in an optical device. In contrast, the resin molded article has a concealing property that a symbol or the like cannot be seen through other than during use.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1 is a schematic cross-sectional view of a resin molded article with a coating film according to a first embodiment as viewed from a direction perpendicular to the center of a through-hole;

FIG. 2A is a schematic cross-sectional view illustrating visibility from a surface of an optical device according to the first embodiment in a state where an LED is turned off;

FIG. 2B is a schematic cross-sectional view illustrating visibility from a surface of the optical device according to the first embodiment in a state where an LED illumination is turned on;

FIG. 3A is a schematic cross-sectional view illustrating a step of forming a primary resin molded component having a through-hole in a method for manufacturing the resin molded article with a coating film according to the first embodiment;

FIG. 3B is a schematic cross-sectional view illustrating a primary resin molded component formed between a first core mold and a cavity mold for a resin molded article in the step of FIG. 3A;

FIG. 3C is a schematic plan view illustrating a case where eight primary resin molded components are simultaneously formed in the step of forming the primary resin molded component having a through-hole;

FIG. 4A is a schematic cross-sectional view illustrating a step of forming a resin molded article with a coating film in a method for manufacturing the resin molded article with a coating film according to the first embodiment;

FIG. 4B is a schematic cross-sectional view illustrating the resin molded article with a coating film formed between a second core mold and the cavity mold for a coating film in the step of FIG. 4A;

FIG. 5A is a schematic cross-sectional view of a resin molded article with a coating film according to a first modification;

FIG. 5B is a partially enlarged view illustrating an undercut portion on a back surface side of a portion A in the vicinity of a through-hole in FIG. 5A;

FIG. 6A is a schematic cross-sectional view of a resin molded article with a coating film according to a second embodiment as viewed from a direction perpendicular to the center of a through-hole;

FIG. 6B is an enlarged cross-sectional view of a portion B in the vicinity of the through-hole of a primary resin molded component constituting the resin molded article with a coating film in FIG. 6A;

FIG. 6C is an enlarged cross-sectional view illustrating a state where a coating film is formed in the vicinity of the through-hole of FIG. 6B;

FIG. 7A is a schematic cross-sectional view of a resin molded article with a coating film according to a second modification;

FIG. 7B is a schematic cross-sectional view of a resin molded article with a coating film according to a third modification;

FIG. 7C is a schematic cross-sectional view of a resin molded article with a coating film according to a fourth modification;

FIG. 8A is a schematic cross-sectional view illustrating a case where a light irradiation unit in the optical device according to the first embodiment is housed in a dark room;

FIG. 8B is a schematic cross-sectional view illustrating a case where a light irradiation unit in a resin molded article with a coating film according to a fifth modification is an optical fiber inserted from the outside of a dark room into the dark room;

FIG. 9A is a schematic cross-sectional view of a resin molded article with a coating film according to a sixth modification;

FIG. 9B is a schematic cross-sectional view of a resin molded article with a coating film according to a seventh modification;

FIG. 9C is a schematic cross-sectional view of a resin molded article with a coating film according to an eighth modification;

FIG. 10 is a schematic cross-sectional view of a resin molded article with a coating film according to a third embodiment as viewed from a direction perpendicular to the center of a through-hole;

FIG. 11A is a schematic cross-sectional view of a resin molded article with a coating film according to a ninth modification as viewed from a direction perpendicular to the center of a through-hole;

FIG. 11B is an enlarged cross-sectional view of a portion D in FIG. 11A;

FIG. 12A is a schematic cross-sectional view of a resin molded article with a coating film according to a tenth modification as viewed from a direction perpendicular to the center of a through-hole;

FIG. 12B is a schematic cross-sectional view of a resin molded article with a coating film according to an eleventh modification as viewed from a direction perpendicular to the center of a through-hole;

FIG. 13 is a plan view of a resin molded article with a coating film according to a fourth embodiment as viewed from an upper surface side;

FIG. 14A is a schematic cross-sectional view taken along line E-E in FIG. 13;

FIG. 14B is a schematic cross-sectional view of a resin molded article with a coating film according to a twelfth modification;

FIG. 15 is a plan view of a resin molded article with a coating film according to a fifth embodiment as viewed from an upper surface side;

FIG. 16A is a schematic cross-sectional view taken along line F-F in FIG. 15;

FIG. 16B is a schematic cross-sectional view of a resin molded article with a coating film according to a thirteenth modification;

FIG. 16C is a schematic cross-sectional view of a resin molded article with a coating film according to a fourteenth modification;

FIG. 16D is a schematic cross-sectional view of a resin molded article with a coating film according to a fifteenth modification;

FIG. 16E is a schematic cross-sectional view of a resin molded article with a coating film according to a sixteenth modification;

FIG. 16F is a schematic cross-sectional view of a resin molded article with a coating film according to a seventeenth modification;

FIG. 17 is a plan view of the resin molded article with a coating film according to the thirteenth modification as viewed from an upper surface side;

FIG. 18A is a schematic cross-sectional view of the resin molded article with a coating film according to the thirteenth modification;

FIG. 18B is a schematic cross-sectional view of a resin molded article with a coating film according to an eighteenth modification;

FIG. 19 is a partial plan view illustrating an island portion at the center, a surrounding through-hole, and a bridge portion at a lower portion of a bottomed hole in FIG. 17;

FIG. 20A is a schematic cross-sectional view taken along line G-G in FIG. 19 of a portion H including a coating film filling the through-hole and the bridge portion at the lower portion of the bottomed hole;

FIG. 20B is a schematic cross-sectional view of a portion H of a resin molded article with a coating film according to a nineteenth modification, the portion H including a coating film filling the through-hole and a bridge portion at a lower portion of a bottomed hole;

FIG. 20C is a schematic cross-sectional view of a portion H of a resin molded article with a coating film according to a twentieth modification, the portion H including a coating film filling a through-hole and a bridge portion at a lower portion of a bottomed hole;

FIG. 21 A is a plan view of a resin molded article with a coating film according to a twenty first modification as viewed from an upper surface side; and

FIG. 21B is a plan view of a resin molded article with a coating film according to a twenty second modification as viewed from an upper surface side.

### DETAILED DESCRIPTION

A resin molded article with a coating film according to a first aspect, includes:

a primary resin molded component having a through-hole; and

an optically transparent coating film covering one end surface of the through-hole of the primary resin molded component and a front surface of the primary resin molded component around the one end surface of the through-hole.

The resin molded article with a coating film according to a second aspect in addition to the first aspect, the coating film may fill a part of the through-hole.

The resin molded article with a coating film according to a third aspect in addition to the first or second aspect, the coating film may cover from the one end surface of the through-hole to a part of an inner wall of the through-hole.

The resin molded article with a coating film according to a fourth aspect in addition to any one of the first to third aspects, the coating film may be filled from the one end surface to another end surface of the through-hole.

The resin molded article with a coating film according to a fifth aspect in addition to any one of the first to fourth aspects, the coating film may have an undercut portion that wraps around from a circumference of the another end surface of the through-hole to a part of a back surface of the primary resin molded component.

The resin molded article with a coating film according to a sixth aspect in addition to any one of the first to fifth aspects, the through-hole may be formed by a vacant space extending from the one end surface to another end surface.

The resin molded article with a coating film according to a seventh aspect in addition to any one of the first to sixth aspects, the coating film may contain at least one selected from a group including a filler, a pigment, and a dye.

The resin molded article with a coating film according to an eighth aspect in addition to any one of the first to seventh aspects, in a back surface of the primary resin molded component, a thickness of an inner edge portion around the another end surface of the through-hole may be thinner than a thickness of an outer edge portion radially outer around the inner edge portion.

The resin molded article with a coating film according to a ninth aspect in addition to any one of the first to eighth aspects, the primary resin molded component may have a thickness changing portion on a back surface, wherein the thickness increases from an inner side toward an outer side in a radial direction around the through-hole.

The resin molded article with a coating film according to a tenth aspect in addition to any one of the first to ninth aspects, the through-hole may have an uneven shape, a grain shape, or a tapered shape on an inner surface of the through-hole, and the primary resin and the coating film are meshed and joined via the uneven shape, the grain shape, or the tapered shape.

The resin molded article with a coating film according to an eleventh aspect in addition to any one of the first to tenth aspects, the coating film may have a surface having an uneven shape or a grain shape.

The resin molded article with a coating film according to a twelfth aspect in addition to any one of the first to eleventh aspects, the coating film may be a cured coating material.

The resin molded article with a coating film according to a thirteenth aspect in addition to any one of the first to twelfth aspects, the coating film may extend from the one end surface of the through-hole to a front surface of the primary resin molded component, and have an undercut portion wrapping around from an end portion of the front surface to a back surface of the primary resin molded component.

An optical device according to a fourteenth aspect, includes:

the resin molded article with a coating film according to the first aspect;

a shielding portion covering a circumference of another end surface of the through-hole and forming a dark room with a back surface of the resin molded article; and

a light irradiation unit configured to irradiate from inside the dark room formed between the back surface of the resin molded article and the shielding portion to another end surface of the through-hole with light.

A method for manufacturing a resin molded article with a coating film according to a fifteenth aspect, the method includes:

preparing a primary resin molded component having a through-hole; and

covering one end surface of the through-hole of the primary resin molded component and a front surface of the primary resin molded component around the one end surface of the through-hole with an optically transparent coating film to obtain a resin molded article with a coating film including the primary resin molded component and the coating film.

The method for manufacturing a resin molded article with a coating film according to a sixteenth aspect in addition to a fifteenth aspect, preparing a primary resin molded component having a through-hole may include:

clamping a first core mold and a cavity mold for a resin molded article of a mold for a resin molded article together, and defining a cavity for a resin molded article corresponding to the primary resin molded component having the through-hole;

introducing a primary resin into the cavity for a resin molded article to form the primary resin molded component having the through-hole; and

opening the first core mold and the cavity mold for a resin molded article to obtain the primary resin molded component having the through-hole.

The method for manufacturing a resin molded article with a coating film according to a seventeenth aspect in addition to a fifteenth or sixteenth aspect, preparing a primary resin molded component having a through-hole may be cutting a primary resin material obtained by molding a primary resin into an optional shape, to obtain the primary resin molded component having the through-hole.

The method for manufacturing a resin molded article with a coating film according to an eighteenth aspect in addition to fifteenth or sixteenth aspect, preparing a primary resin molded component having a through-hole may be forming a primary resin molded component by shaping with a 3D printer.

The method for manufacturing a resin molded article with a coating film according to a nineteenth aspect in addition to any one of fifteenth to eighteenth aspects, covering one end surface of the through-hole of the primary resin molded component and a front surface of the primary resin molded component around the one end surface of the through-hole with an optically transparent coating film may include:

placing the primary resin molded component having the through-hole, on a second core mold, and clamping the second core mold and a cavity mold for a coating film together to define a cavity for a coating film, the cavity including the one end surface of the through-hole;

filling the cavity for a coating film with an optically transparent coating material to form a coating film, the coating film, with the coating material, covering the one end surface of the through-hole and a front surface of the primary resin molded component around the one end surface of the through-hole; and

opening the second core mold and the cavity mold for a coating film and pushing out a resin molded article with a coating film having the coating film from inside the second core mold to obtain the resin molded article with a coating film.

The method for manufacturing a resin molded article with a coating film according to a twentieth aspect in addition to nineteenth aspect, in the course of filling for the cavity, the through-hole may be filled with the coating material.

The method for manufacturing a resin molded article with a coating film according to a twenty-first aspect in addition to nineteenth or twentieth aspect, the second core mold may be provided with a recess that introduces the coating material to a back surface of the through-hole of the primary resin molded component, the back surface facing the second core mold, and

in the course of filling for the cavity, the coating material may be introduced from a front surface facing the cavity mold for a coating film to the back surface, to form a wraparound portion extending from one end surface of the through-hole through the front surface of the primary resin molded component and wrapping around from an end portion of the front surface to the back surface of the primary resin molded component.

Hereinafter, a resin molded article with a coating film, a method for manufacturing the same, and an optical device according to an embodiment of the present disclosure will be described with reference to the accompanying drawings.

### First Embodiment

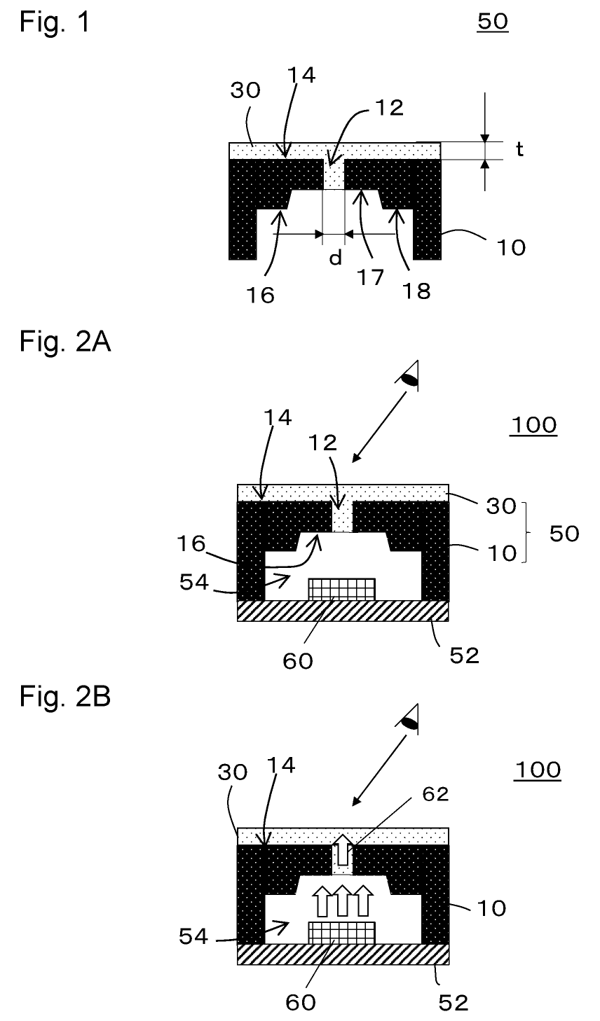

FIG. 1 is a schematic cross-sectional view of a resin molded article with a coating film 50 according to a first embodiment as viewed from a direction perpendicular to the center of a through-hole 12. FIG. 2A is a schematic cross-sectional view illustrating visibility from a surface of an optical device 100 according to the first embodiment in a state where an LED 60 is turned off. FIG. 2B is a schematic cross-sectional view illustrating visibility from a surface of the optical device 100 according to the first embodiment in a state where an LED 60 is turned on.

### Resin molded article with coating film

As illustrated in FIG. 1, the resin molded article with a coating film 50 according to the first embodiment includes a primary resin molded component 10 having a through-hole 12 and a optically transparent coating film 30 filling the through-hole 12. The coating film 30 covers one end surface of the through-hole 12 and the front surface 14 of the primary resin molded component 10 around the one end surface of the through-hole 12. Note that, for example, even a fine through-hole having a hole diameter d of 0.05 mm (50 μm) to 0.2 mm (200 μm) can be filled with the coating film because the coating film 30 is formed using a low-viscosity coating material as described later, and high-definition display using the fine through-hole can be performed. Furthermore, the coating film 30 can be made thin, for example, about 0.05 mm to 1 mm in film thickness, and can also be provided with grain and the like, so that the decoration quality is high.

Hereinafter, components constituting the resin molded article with a coating film 50 will be described.

### Primary resin molded component

The primary resin molded component 10 is formed by injection-molding a primary resin. As the primary resin, any normal injection-moldable resin can be used, but it is particularly preferable to use a thermoplastic resin. As the thermoplastic resin, for example, polyethylene, polypropylene, polyamide, ABS resin, polyvinyl chloride, polystyrene, polyvinyl acetate, polyurethane, acrylic resin, polycarbonate, polyester, and the like can be used, but resins other than those described herein are also acceptable. Note that, since the thermosetting resin has a crosslinked structure, the molecular structure on the surface of the molded article is stable, and the coating material for in-mold coating tends to be difficult to adhere. However, there is no problem even with a thermosetting resin as long as the thermosetting resin can sufficiently secure adhesion to a coating material.

In addition, the primary resin molded component 10 may be colored in black that does not transmit light. As a result, a dark room can be formed on the back surface side when used in an optical device.

### Through-hole

The primary resin molded component 10 has a through-hole 12. The through-hole 12 in the primary resin molded component 10 preferably has a hole diameter d of 0.05 mm (50 μm) or more and 5 mm or less, for example.

Note that the upper limit value of the hole diameter of the through-hole 12 is an example and is not limited to the above range. For example, in a case where a through-hole of 5 mm or more is required depending on the application, there is no problem even if the through-hole 12 exceeding the above range is formed.

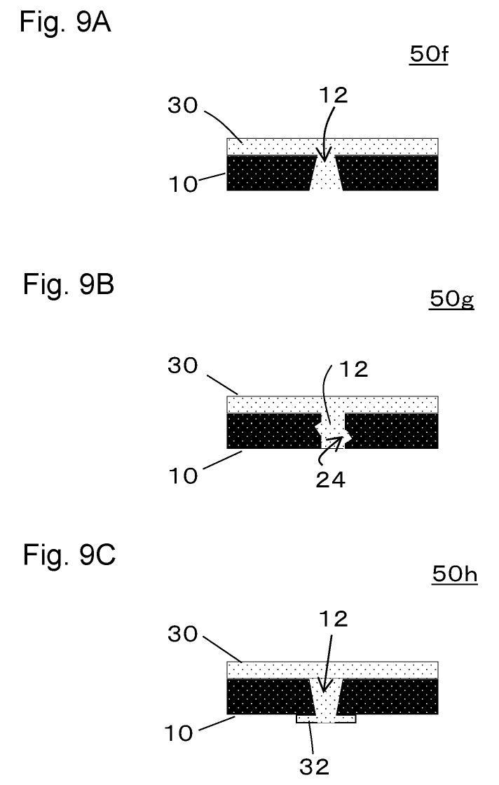

In addition, the through-hole 12 is not limited to a case where the same cross- sectional shape is continuous in the thickness direction between one end surface and the other end surface of the through-hole 12, and the through-hole 12 may have a cross-sectional shape that varies between both ends. In addition, as will be described later, the through-hole may have an uneven shape (FIG. 9B), a grain shape, or a tapered shape (FIG. 9A, 9C) on the inner surface. As a result, the primary resin and the coating film are engaged with each other and joined via the uneven shape, the grain shape, or the tapered shape.

As illustrated in FIG. 1, in the primary resin molded component 10, for example, the thickness of the inner edge portion 17 around another end surface of the through-hole 12 may be thinner than the thickness of the outer edge portion 18 radially outer around the inner edge portion 17. By making the thickness of the inner edge portion 17 thinner than the thickness of the outer edge portion 18, the length of the through-hole 12 can be shortened, and attenuation of light passing through the through-hole 12 can be suppressed. In addition, by reducing the thickness of the inner edge portion 17 in the stage of forming the primary resin molded component 10, it is possible to suppress the occurrence of distortion due to sink marks of the primary resin around the through-hole 12.

### Coating film

The coating film 30 is obtained by curing a optically transparent coating material. The optically transparent coating material may be, for example, a two-liquid thermosetting urethane-based coating material, a two-liquid curable epoxy-based coating material, a one-liquid thermosetting acrylic coating material, or an ultraviolet curable coating material. The coating film 30 may contain additives such as a filler, a colorant, a curing accelerator, and a release agent. The filler may be, for example, a metallic filler having glossiness or an optical interference pigment such as a polarizing pearl having high optical transparency.

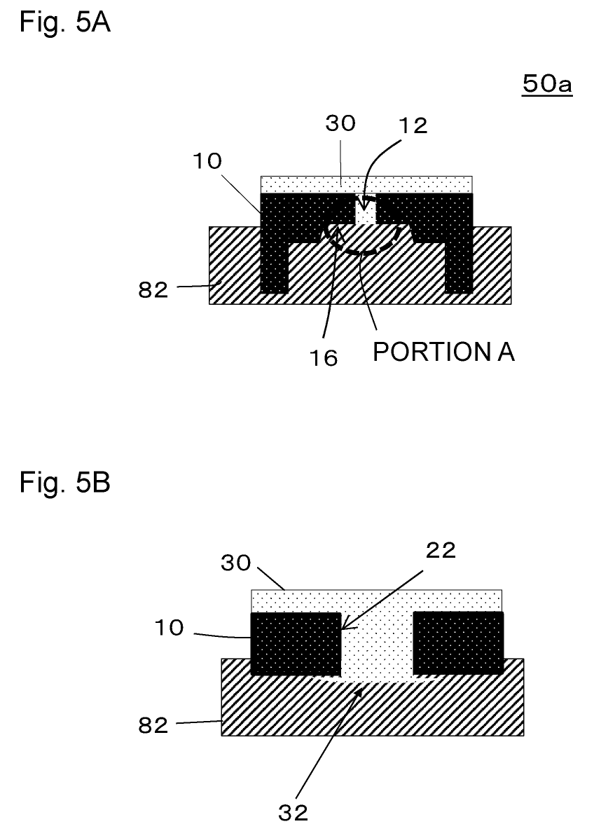

The coating film 30 fills the through-hole 12 of the primary resin molded component 10. In addition, the coating film 30 covers one end surface of the through-hole 12 and the front surface 14 of the primary resin molded component 10 around the one end surface of the through-hole 12. The thickness t of the coating film 30 covering the front surface 14 of the primary resin molded component 10 is, for example, 0.05 mm or more and 1 mm or less. Furthermore, the thickness t may be, for example, 0.1 mm or more and 0.5 mm or less. Note that the coating film 30 may have an undercut portion 32 that wraps around the circumference of another end surface of the through-hole 12 as illustrated in a first modification to be described later (FIG. 5B).

The coating film 30 may have a surface having an uneven shape or a grain shape. Accordingly, high decoration quality can be obtained. In addition, the coating material for the coating film 30 to be used is a two-liquid curable coating material having high fluidity or a one-liquid type coating material to be injected into a mold in a state where a main agent and a curing agent are mixed in advance. Therefore, the uneven shape or the grain shape of the mold surface can be transferred with high accuracy.

### Optical device

As illustrated in FIGS. 2A and 2B, the optical device 100 according to the first embodiment includes the above-described resin molded article with a coating film 50, a substrate (shielding portion) 52 that covers the circumference of the other end surface of the through-hole 12 and forms a dark room 54 with the back surface 16 of the resin molded article with a coating film 50, and an LED (light irradiation unit) 60 provided in the dark room 54. As illustrated in FIG. 2A, in a state where the LED 60 is turned off, the dark room 54 is formed between the back surface 16 of the resin molded article with the coating film 50 and the substrate 52, the dark room 54 includes the other end surface of the through-hole 12 and the through-hole 12 cannot be visually recognized from the surface. Contrarily, as illustrated in FIG. 2B, in a state where the LED 60 is turned on, the light 62 from the LED 60 reaches the surface through the through-hole 12, so that the through-hole 12 can be visually recognized from the front surface of the resin molded article with the coating film 50.

Therefore, the optical device 100 enables high decoration quality and high-definition optical display, and contrarily, has a concealing property that a symbol or the like cannot be seen through other than during use.

Hereinafter, among the components constituting the optical device 100, components other than the resin molded article with a coating film 50 will be described.

### Shielding portion

The shielding portion 52 may be, for example, a substrate. The substrate 52 only needs to cover the circumference of the other end surface of the through-hole 12 to form the dark room 54 with the back surface 16 of the resin molded article with a coating film 50. Note that, in FIGS. 2A and 2B, the entire back surface 16 of the resin molded article with a coating film 50 is covered with the substrate 52, but the present invention is not limited thereto, and it is sufficient that a dark room can be formed by partially covering the back surface 16. The shielding portion 52 is not limited to having a flat plate shape, and may have a curved surface shape.

In addition, the shielding portion 52 may take light from a light source into the dark room 54 by using a material having optical transparency in part.

### Light irradiation unit

The light irradiation unit 60 may be, for example, an LED, a light bulb, or the like that can be placed in the dark room 54. Alternatively, as will be described later, the light irradiation unit 60 may be an optical fiber that guides light from an external light source into the dark room 54, or a combination of a shielding portion and a light source, the shielding portion having optical transparency in part so as to be able to transmit light from an external light source and take light into the dark room 54.

### Method for manufacturing resin molded article with coating film (method for manufacturing in-mold coated article)

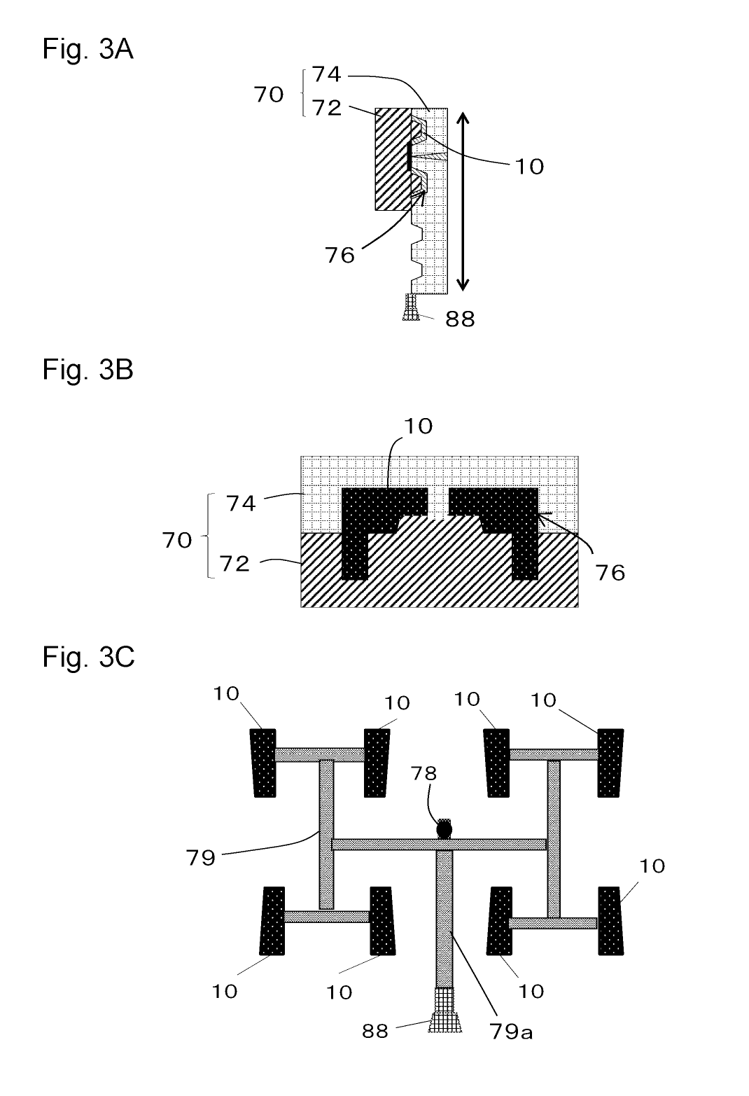

FIG. 3A is a schematic cross-sectional view illustrating a step of forming a primary resin molded component 10 having a through-hole in the method for manufacturing a resin molded article with a coating film 10 according to the first embodiment. FIG. 3B is a schematic cross-sectional view illustrating the primary resin molded component 10 formed between a first core mold 72 and a cavity mold for a resin molded article 74 in the step of FIG. 3A. FIG. 3C is a schematic plan view illustrating a case where eight primary resin molded components 10 are simultaneously formed in the step of forming the primary resin molded component 10 having the through-hole.

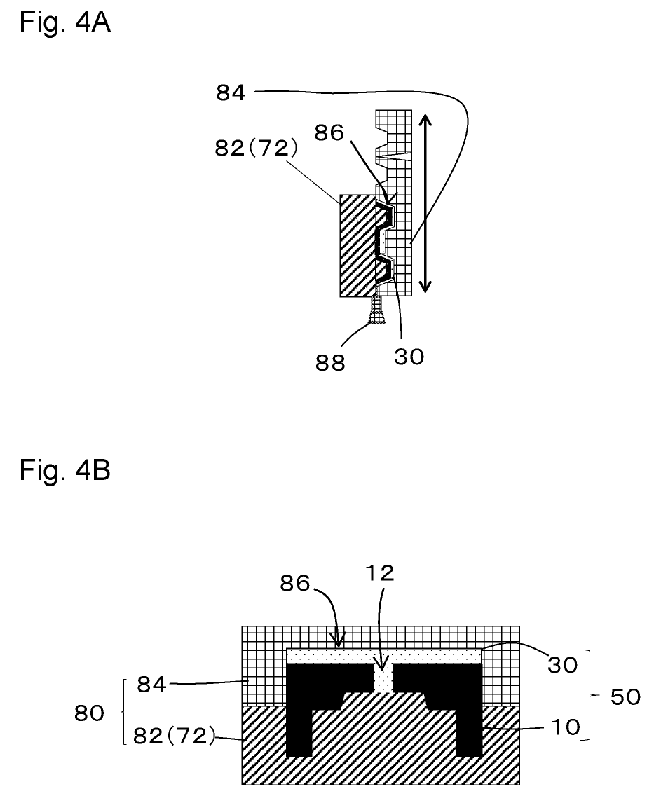

Hereinafter, a method for manufacturing a resin molded article with a coating film according to the first embodiment will be described. This method for manufacturing a resin molded article with a coating film includes a step of forming a resin molded article (FIGS. 3A, 3B, and 3C) and a step of injecting a coating material (FIG. 4A, FIG. 4B).

### Step of forming primary resin molded component

The primary resin molded component 10 is formed using a mold for a resin molded article 70 among the in-mold coating mold set. Specifically, as illustrated in FIGS. 3A and 3B, the first core mold 72 and the cavity mold for a resin molded article 74 of the mold for a resin molded article 70 are clamped together to define a cavity for a resin molded article 76 corresponding to the resin molded article 10. Next, the primary resin is introduced from the resin injection gate 78 to the cavity for a resin molded article 76 via the runner gate 79. Thus, the resin molded article 10 made of the primary resin is formed.

After the primary resin is cured, the first core mold 72 and the cavity mold for a resin molded article 74 are opened to obtain the resin molded article 10. Note that, as illustrated in FIG. 3C, when the primary resin molded component 10 is small, eight primary resin molded components 10 can be simultaneously formed.

Note that, when the primary resin molded component 10 is formed, for example, as illustrated in FIG. 3C, a runner gate 79 may be formed simultaneously with the formation of the primary resin molded component 10. The runner gate 79 guides the coating material from the coating material injection head 88 to a cavity for a coating film 86 when the first core mold 72 is moved to a position facing a cavity mold for a coating film 84. In this case, in the step of forming the primary resin molded component 10, it is necessary to guide the primary resin from the resin injection gate 78 also to a path 79a toward the coating material injection head 88 (after moving the first core mold), separately from a path from the resin injection gate 78 to the cavity for a resin molded article 76.

However, it is not always necessary to manufacture the primary resin molded component by injection molding, and for example, the primary resin molded component may be formed in advance by cutting or shaping with a 3D printer. The primary resin molded component obtained by various methods may be set in a mold or a jig for forming a coating film, and a resin molded article with a coating film may be manufactured through a manufacturing method in which the through-hole and the surface of the primary resin molded component are covered with a coating material. In addition, the method for obtaining the primary resin molded component is not limited to the above, and other methods may be used as long as the method is capable of obtaining the resin molded article with a coating film according to the present disclosure.

### Step of forming resin molded article with coating film

FIG. 4A is a schematic cross-sectional view illustrating a step of forming the resin molded article with a coating film in the method for manufacturing the resin molded article with a coating film 50 according to the first embodiment. FIG. 4B is a schematic cross-sectional view illustrating the resin molded article with a coating film 50 formed between a second core mold 82 and a cavity mold for a coating film 84 of a mold for coating film 80 in the step of FIG. 4A.

(1) As illustrated in FIGS. 4A and 4B, the primary resin molded component 10 is placed on the second core mold 82 at the time of forming the coating film. A coating material injection head 88 is attached to the cavity mold for a coating film 84, and the coating material injection head 88 is disposed so as to be close to the runner gate 79. As illustrated in FIG. 4B, when the second core mold 82 and the cavity mold for a coating film 84 are clamped together, the cavity for a coating film 86 is formed between the resin molded article 10 and the cavity mold for a coating film 84.

Note that the same mold may be continuously used for the first core mold 72 of FIG. 3A and the second core mold of FIG. 4A. That is, the primary resin molded component 10, which has been formed on the first core mold 72 in the step of forming the primary resin molded component 10, may be kept placed on the first core mold 72 to be used as the second core mold 82 (72) in the step of forming the resin molded article with a coating film.

In addition, the cavity mold for a resin molded article 74 and the cavity mold for a coating film 84 may be arranged in parallel, and the first core mold 72 may be moved in parallel from a position facing the cavity mold for a resin molded article 74 to a position facing the cavity mold for a coating film 84 as illustrated by an arrow in FIG. 4A.

(2) Next, the optically transparent coating material is introduced from the coating material injection head 88 into the cavity for a coating film 86 through the runner gate 79. The coating material fills the cavity for a coating film 86 to form the coating film 30.

The coating material to be used may be any optically transparent resin. For example, the coating material injection head 88 to be normally used may be a type of injection head for injecting two-liquid coating material, the injection head colliding multiple coating materials such as a main agent and a curing agent, and a filler or a colorant to mix them within the head. Alternatively, there may be used an injection head that mixes the main agent and the curing agent, and the filler or the colorant in advance in a tank, and just injects the resulting coating material as one liquid without colliding them for mixing.

Note that the viscosity of the coating material is, for example, in the range of 50 to 1,000 mPa*s between 60°C and 100°C. The viscosity is more preferably 50 to 500 mPa*s, still more preferably 50 to 300 mPa*s. When the viscosity is 50 mPa*s or more, the leakage of the coating material from the mold and the jig is relatively easily prevented, and when the viscosity is 300 mPa*s or less, the fluidity of the coating material is further improved in the case of thin film.

In the case of two-liquid curing, the dispersibility at the time of collision mixing in the injection head is enhanced when the main agent, the curing agent, and the colorant having the same viscosity region are used, and thus it is desirable to use a coating material in which all of the main agent, the curing agent, and the colorant fall within the above viscosity range. Also in the case of one liquid, the above viscosity range is desirable.

(3) As illustrated in FIG. 4B, the coating material filled in the cavity for a coating film 86 is then cured. Note that the curing method is not limited to the case with the lapse of time as described above, and the curing may be performed by heating. Alternatively, a part of the mold may be of a transparent material through which the coating material is irradiated through the mold made of the transparent material with ultraviolet light or the like to be cured.

(4) After the coating film 30 is cured, the resin molded article with a coating film (in-mold coated and molded article) 50 is pushed up in the Z direction from the second core mold 82 (72) by an ejector pin (not illustrated) provided inside the second core mold 82 (72) and released. Note that the number of the ejector pins may be one or more, or two or three or more. In addition, the method of driving the ejector pin may be any of commonly used method, and may be, for example, any of hydraulic, pneumatic, and mechanical driving.

As described above, the resin molded article with a coating film (in-mold coated and molded article) 50 can be obtained.

Note that, in this step, a two-color molding method using a resin to be molded capable of securing adhesion to the primary resin by two-color molding is also an option, instead of the in-mold coating method using the coating material. However, in the two-color molding method, the scratch resistance of the surface of the thermoplastic resin is low, and the viscosity of the resin to be molded itself is higher than the viscosity of the coating material to be used for in-mold coating of the present disclosure. For this reason, there is also a problem in which the filling property of the resin to be molded into the through-hole and the front surface is low in the thin film, and the thickness of the layer on the front surface of the molded resin increases, resulting in an increase in the total thickness of the component. In addition, this increases the difference in thickness of the molded resin having transparency between the through-hole portion and the other portion, and this is likely to cause problems in appearance such as occurrence of sink marks on the surface of the molded article caused by the difference in amount of shrinkage due to the difference in thickness of the transparent resin (molded resin). In addition, when a design is desired for making grain on the surface of the transparent resin (molded resin), the thickness of the transparent resin (molded resin) increases. This increases the thickness of the transparent resin (molded resin) layer through which light passes which exits from a through-hole formed in the primary resin molded component. This then increases the distance to the surface on which the grain is formed, and causes diffusion of light to be likely to occur. Furthermore, since light diffusion occurs due to the grain shape of the surface, display blurring of the symbol mark visually recognized is likely to occur, which is also a factor of lowering visibility.

From the above factors in the two-color molding method, an advantage is caused by manufacturing through a method of production that uses in-mold coating method using a coating material having high fluidity to easily fill the coating material into the part having a thin film and a fine shape as compared with the two-color molding method.

### First Modification

FIG. 5A is a schematic cross-sectional view of a resin molded article with a coating film 50a according to a first modification. FIG. 5B is a partially enlarged view illustrating the undercut portion 32 on the back surface 16 side in the vicinity of the through-hole 12 in FIG. 5A.

As illustrated in FIG. 5B, the resin molded article with a coating film 50a according to the first modification has an undercut portion 32 in which the coating material wraps around from the circumference of another end surface of the through-hole 12 to the back surface 16. This is because the coating material forming the coating film 30 has a low viscosity, and therefore slightly leaks out to the circumference from the other end surface of the through-hole 12 of the primary resin molded component 10. The undercut portion 32 enhances adhesion between the primary resin molded component 10 and the coating film 30.

Note that, in the primary resin molded component 10, grain 22 may be provided on the inner surface of the through-hole 12. By providing the grain 22 on the inner surface of the through-hole 12, the coating film 30 filling the through-hole 12 is less likely to be peeled off.

In addition, a structure that facilitates light transmission may be provided inside the through-hole 12. This improves the transmission efficiency of light passing through the through-hole 12.

Such structures include, for example, making the inner wall surface of the through-hole into a smooth surface, a mirror surface, a polished surface, a surface-treated surface, a curved surface, a surface on which fine ribs are formed (groove or linear processing). This causes light passing through the through-hole 12 to be more likely to be reflected by the wall surface of the through-hole 12 or to escape to the outside, resulting in increased transmittance of light.

In addition, for example, a surface for increasing the transmittance may be formed not on the inner wall surface but on the lower surface of the filled resin by a hologram or the like, for example.

In addition, a hologram function may be provided toward the upper surface, and such a shape and function may be given in a subsequent step.

In addition, to further increase the transmittance, a low refractive index material may be added to the coating film to lower the refractive index of the coating film itself, thereby improving the light transmittance.

### Second Embodiment

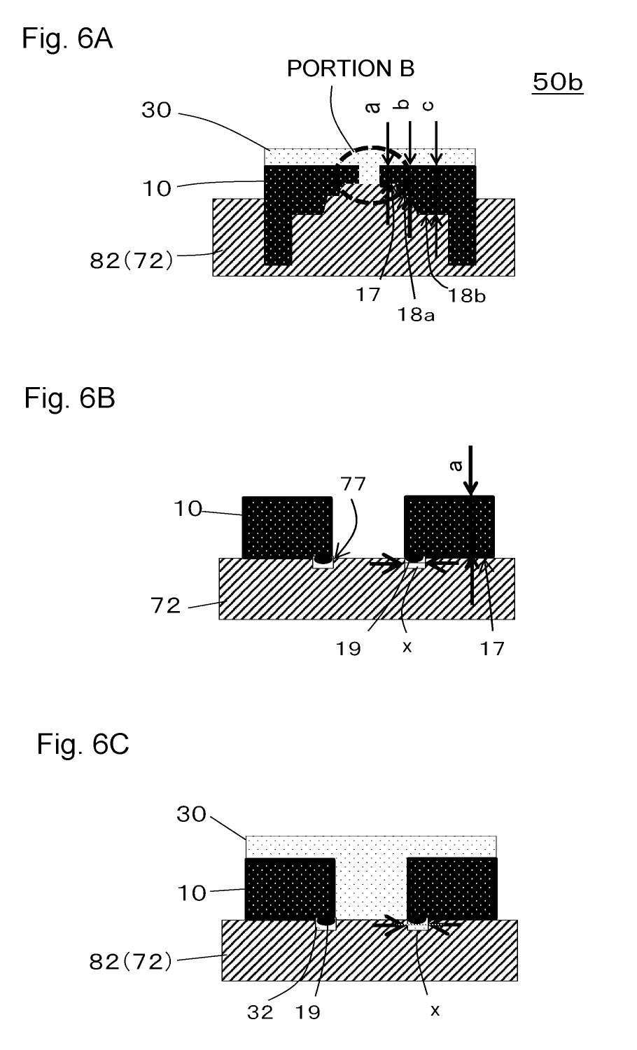

FIG. 6A is a schematic cross-sectional view of the resin molded article with a coating film 50b according to a second embodiment as viewed from a direction perpendicular to the center of the through-hole 12. FIG. 6B is an enlarged cross-sectional view of a portion B in the vicinity of the through-hole 12 of the primary resin molded component 10 constituting the resin molded article with a coating film 50b in FIG. 6A. FIG. 6C is an enlarged cross-sectional view illustrating a state where the coating film 30 is formed in the vicinity of the through-hole 12 in FIG. 6B.

The resin molded article with a coating film 50b according to the second embodiment is different from the first embodiment in that the primary resin molded component 10 has a thickness changing portion in which the thickness increases in three stages of the inner edge portion 17 around another end surface of the through-hole 12, and the outer edge portion 18a and the outer edge portion 18b on the radially outer side of the inner edge portion 17. Specifically, the thickness a of the inner edge portion 17, the thickness b of the outer edge portion 18a, and the thickness c of the outer edge portion 18b have a magnitude relationship of a < b< c. Changing the thickness in multiple stages makes it possible to suppress decrease in strength due to a rapid thickness change, or occurrence of sink marks at the time of forming the primary resin molded component. Note that the thickness changing portion is not limited to a case of the stepped shape as described above, and the thickness may continuously change.

In addition, in a case where a recess 77 having a small length x in the radial direction may be provided in the vicinity of the through-hole 12 of the first core mold 72 in the stage of forming the primary resin molded component, as illustrated in FIG. 6B, there may be a case where the viscosity of the primary resin cannot cause the recess 77 to be filled throughout the length x and a protrusion 19 is formed. Note that the length x is, for example, 0.5 mm or less. In addition, a relationship of x < a < b < c may be satisfied.

In such a case, in the stage of forming the resin molded article with a coating film, the coating material having a low viscosity fills the gap between the protrusion 19 in the vicinity of the through-hole 12 and the recess of the second core mold 82 (72) to form the undercut portion 32. The undercut portion 32 enhances adhesion between the primary resin molded component 10 and the coating film 30.

### Second to fourth Modifications

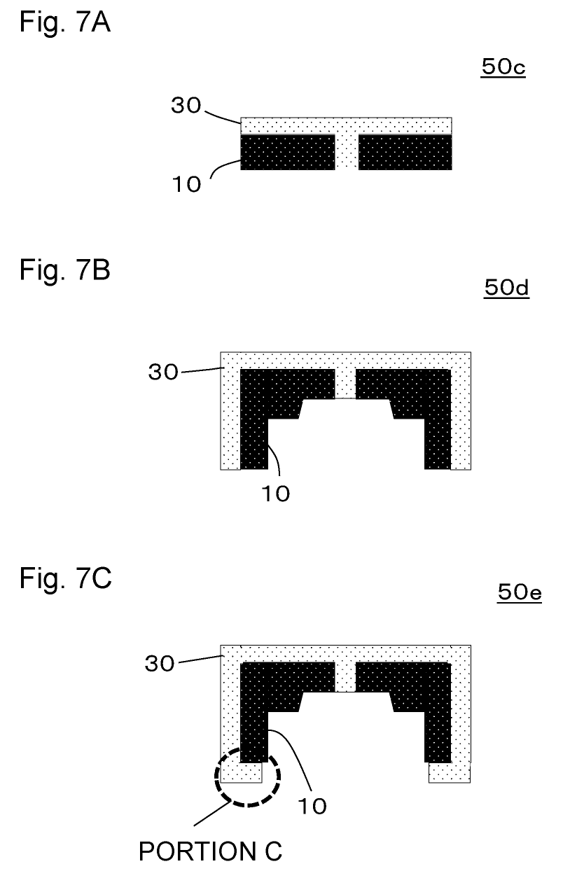

FIG. 7A is a schematic cross-sectional view of a resin molded article with a coating film 50c according to a second modification. FIG. 7B is a schematic cross-sectional view of a resin molded article with a coating film 50d according to a third modification. FIG. 7C is a schematic cross-sectional view of a resin molded article with a coating film 50e according to a fourth modification.

The resin molded article with a coating film 50c according to the second modification is characterized in that the primary resin molded component 10 has a flat plate shape. The resin molded article with a coating film 50d according to a third modification is characterized in that the coating film 30 is provided so as to cover not only the upper surface but also the side surfaces of the primary resin molded component 10. The resin molded article with a coating film 50e according to a fourth modification is characterized in that the coating film 30 has wraparound (C portion) from the front surface to the back surface side of the primary resin molded component 10.

As illustrated in FIGS. 7A to 7C, the shapes of the primary resin molded component 10 and the coating film 30 may be appropriately selected according to the application.

### Fifth Modification

### Optical device

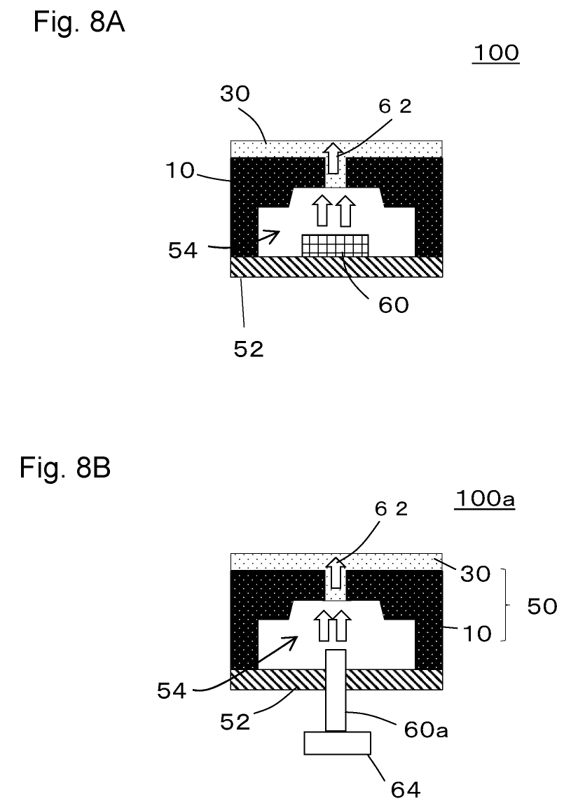

FIG. 8A is a schematic cross-sectional view illustrating a case where the LED that is the light irradiation unit 60 in the optical device 100 according to the first embodiment is housed in the dark room 54. FIG. 8B is a schematic cross-sectional view illustrating a case where the light irradiation unit in the resin molded article with a coating film 100a according to a fifth modification is the optical fiber 60a inserted from the outside to the inside of the dark room.

As illustrated in FIG. 8B, an optical device 100a according to the fifth modification is different from that of the first embodiment in including a resin molded article with a coating film 50, a substrate 52 serving as a shielding portion, and an optical fiber 60a serving as a light irradiation unit. The light irradiation unit is not limited to an LED, a light bulb, or the like placed in the dark room 54 as in the optical device according to the first embodiment, and may be an optical fiber inserted into the dark room 54 from the outside of the dark room 54. The dark room 54 is formed by covering the circumference of another end surface of the through-hole 12 with the substrate 52 that is a shielding portion. In addition, the optical fiber 60a, which is a light irradiation unit, guides light from the light source 64 outside the dark room 54 formed by the shielding portion 52 to the inside of the dark room 54, and irradiates another end surface of the through-hole 12 with the light 62.

According to this optical device, when another end surface of the through-hole 12 is not irradiated with light from the optical fiber 60a serving as a light irradiation unit (illumination off), the dark room 54 remains dark, so that the through-hole 12 cannot be visually recognized from one end surface of the through-hole 12. Contrarily, when another end surface of the through-hole 12 is irradiated with the light 62 from the optical fiber 60a serving as a light irradiation unit (illumination on), the light 62 is transmitted from another end surface of the through-hole 12 to one end surface of the through-hole 12 through the coating film 30 containing the optically transparent resin, and the shape of the through-hole 12 shines, so that the shape of the through-hole 12 can be visually recognized. Therefore, when the illumination is turned off, only the coating film 30 covering the surface of the primary resin molded component 10 can be visually recognized, and when the illumination is turned on, the shape of the through-hole 12 can be visually recognized. That is, for example, by forming the symbol in the shape of the through-hole 12, the symbol formed by the through-hole 12 can be concealed in the illumination off state, and the symbol can be visually recognized in the illumination on state.

In addition, as a method of taking light from the external light source 64 into the dark room 54 without using the optical fiber 60a, for example, a material having optical transparency may be used for a part or the whole of the substrate 52.

### Sixth to Eighth Modifications

FIG. 9A is a schematic cross-sectional view of a resin molded article with a coating film 50f according to a sixth modification. FIG. 9B is a schematic cross-sectional view of a resin molded article with a coating film 50g according to a seventh modification. FIG. 9C is a schematic cross-sectional view of a resin molded article with a coating film 50h according to an eighth modification.

The resin molded article with a coating film 50f according to the sixth modification is characterized in that the through-hole 12 of the primary resin molded component 10 has a tapered shape in which the hole diameter increases from the front surface toward the back surface. By making the back surface side large, a large amount of light can be guided. On the other hand, by making the front surface side small, a diaphragm can be applied, diffusion can be suppressed, and display blurring can be suppressed.

The resin molded article with a coating film 50g according to the seventh modification is characterized in that the through-hole 12 of the primary resin molded component 10 has an uneven portion 24 on the inner surface. The uneven portion 24 may be formed by roughening, for example.

Note that this shape is not necessarily manufactured by injection molding, and may be formed by, for example, cutting or partially blasting the wall surface of the through-hole 12 in advance. Alternatively, the through-hole 12 of the primary resin molded component may be formed using a 3D printer. It is sufficient that an appropriate method is selected.

The resin molded article with a coating film 50h according to an eighth modification is characterized in that the through-hole 12 of the primary resin molded component 10 has a tapered shape in which the hole diameter increases from the back surface toward the front surface, and the undercut portion 32 of the coating film 30 is provided on the back surface side. For the undercut portion 32, a wraparound may be formed on the back surface side by using a coating material having a low viscosity.

According to the resin molded articles with a coating film 50f to 50h according to the sixth to eighth modifications, the coating film 30 is hardly peeled off from the primary resin molded component 10 due to the shape itself of the through-hole 12 or the undercut portion 32. This makes it possible to increase the strength of the resin molded articles with a coating film 50f to 50h.

### Third Embodiment

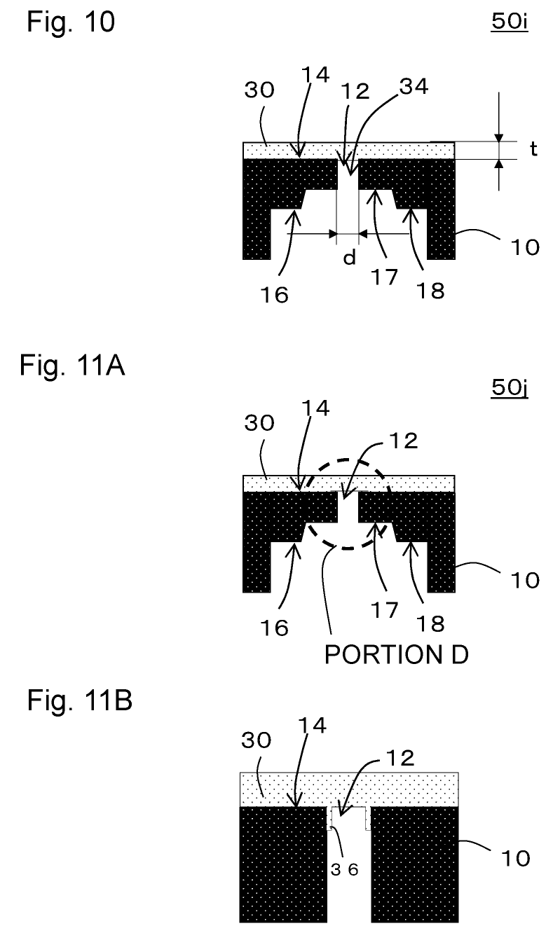

FIG. 10 is a schematic cross-sectional view of the resin molded article with a coating film 50i according to a third embodiment as viewed from a direction perpendicular to the center of the through-hole 12.

The resin molded article with a coating film 50i according to the third embodiment is different from the resin molded article with a coating film according to the first embodiment in that the through-hole 12 is not filled with a coating material and is formed by a vacant space extending from one end surface to the other end surface. Since the through-hole 12 is not filled with the coating material, even when the coating material contains the filling material, the through-hole 12 does not have the coating material. This makes it possible to avoid the filling material from stagnating in the through-hole and increasing in the concentration to make orientation difficult on the surface of the resin molded body. In addition, also when the coating material does not contain the filling material, not filing coating material in the through-hole makes it possible to suppress the occurrence of wrinkles due to the occurrence of a difference in shrinkage rate between the through-hole having an increased resin thickness and the other part when the through-hole is filled with the coating material.

Note that, the step of forming an optically transparent coating film may be such that when the second core mold 82 and the cavity mold for a coating film 84 are clamped together, the second core mold 82 or the cavity mold for a coating film 84 is inserted through the through-hole 12, and thereby, the inside of the through-hole 12 is not included in the cavity for a coating film. As a result, the through-hole 12 can be formed with the vacant space 34 extending from one end surface to the other end surface without filling the through-hole 12 with the coating material. Note that, as illustrated in a ninth modification described later, it is actually difficult to form a complete "vacant space". Therefore, as illustrated in the enlarged view of FIG. 11B, a case may be included where a very small amount of coating material covers a part of the inner wall from one end surface of the through-hole 12.

### Ninth Modification

FIG. 11A is a schematic cross-sectional view of a resin molded article with a coating film 50j according to a ninth modification as viewed from a direction perpendicular to the center of the through-hole. FIG. 11B is an enlarged cross-sectional view of a portion D in FIG. 11A.

At first glance, the resin molded article with a coating film 50j according to the ninth modification seems to have the through-hole 12 filled with no coating material, similarly to the resin molded article with a coating film according to the third embodiment. However, as illustrated in the enlarged view of FIG. 11B, a very small amount of coating material 36 may cover a part of the inner wall from one end surface of the through-hole 12. For example, such a coating material is called a "catching portion". The "catching portion" 36 may be unintentionally formed due to the entry of the coating material into the gap of the mold.

### Tenth and Eleventh Modifications

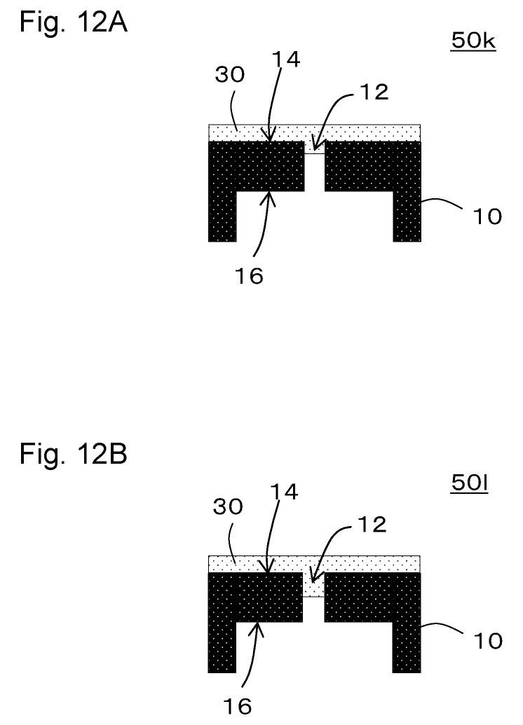

FIG. 12A is a schematic cross-sectional view of a resin molded article with a coating film 50k according to a tenth modification as viewed from a direction perpendicular to the center of a through-hole 12. FIG. 12B is a schematic cross-sectional view of a resin molded article with a coating film 50l according to an eleventh modification as viewed from a direction perpendicular to the center of the through-hole 12.

As illustrated in FIG. 12A, in the resin molded article with a coating film 50k according to the tenth modification, a part of the through-hole 12 is filled with a coating material, for example, a part of the through-hole 12 is filled with a coating film having a thickness of 20% of the length in the extending direction of the through-hole 12. As illustrated in FIG. 12B, in the resin molded article with a coating film 50l according to the eleventh modification, a part of the through-hole 12 is filled with the coating material, for example, with the coating film having a thickness of 50% of the length in the extending direction of the through-hole 12.

As illustrated in the tenth and eleventh modifications, the coating film 30 may fill a part of the through-hole 12. For example, a part of the through-hole 12 may be filled with a portion having a thickness of 5 to 100% of the length in the extending direction of the through-hole 12. Furthermore, a part of the through-hole 12 may be filled with a portion having a thickness of 20 to 50% of the length in the extending direction of the through-hole 12. Within the above range, sink marks on the surface of the coating film 30 including the through-hole 12 can be suppressed. In addition, also when the coating material contains a filling material, optical characteristics can be obtained by setting the thickness within the above range.

### Fourth Embodiment and Twelfth Modification

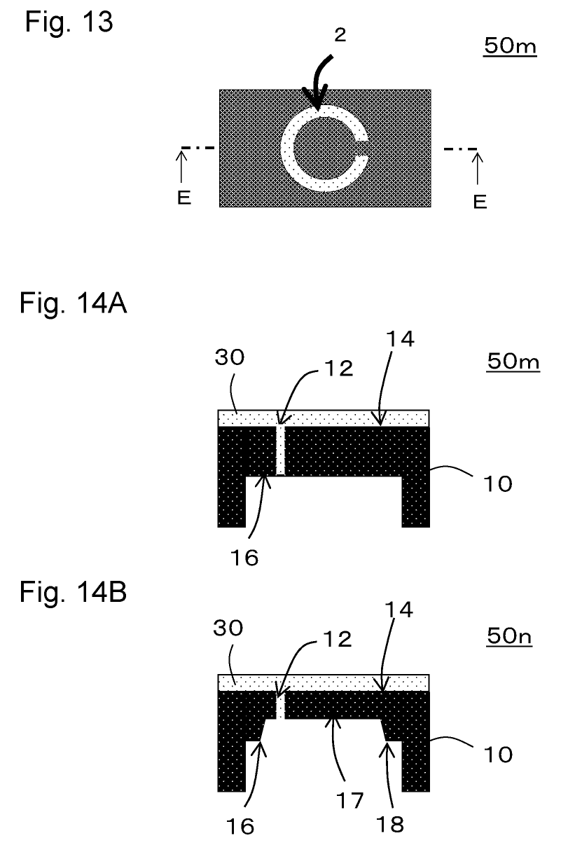

FIG. 13 is a plan view of a resin molded article with a coating film 50m according to a fourth embodiment as viewed from the upper surface side. FIG. 14A is a schematic cross-sectional view taken along line E-E in FIG. 13. FIG. 14B is a schematic cross-sectional view of a resin molded article with a coating film 50n according to a twelfth modification.

As illustrated in the plan view of FIG. 13, the resin molded article with a coating film 50m according to the fourth embodiment forms a symbol 2 of an alphabet C. As illustrated in FIG. 14A, the symbol 2 is formed by a through-hole 12, and can be visually recognized from the surface by emitting light from the lower portion of the through-hole 12. In FIG. 14A, the back surface 16 has a single step shape. In addition, in the twelfth modification illustrated in FIG. 14B, the back surface 16 has a multiple step shape having an inner edge portion 17 and an outer edge portion 18.

Note that by adjusting the width of a bridge portion, not only C of the alphabet can be displayed as a symbol, but also O of the alphabet can be displayed, for example, by narrowing the width of the bridge portion.

### Fifth Embodiment and Thirteenth Modification

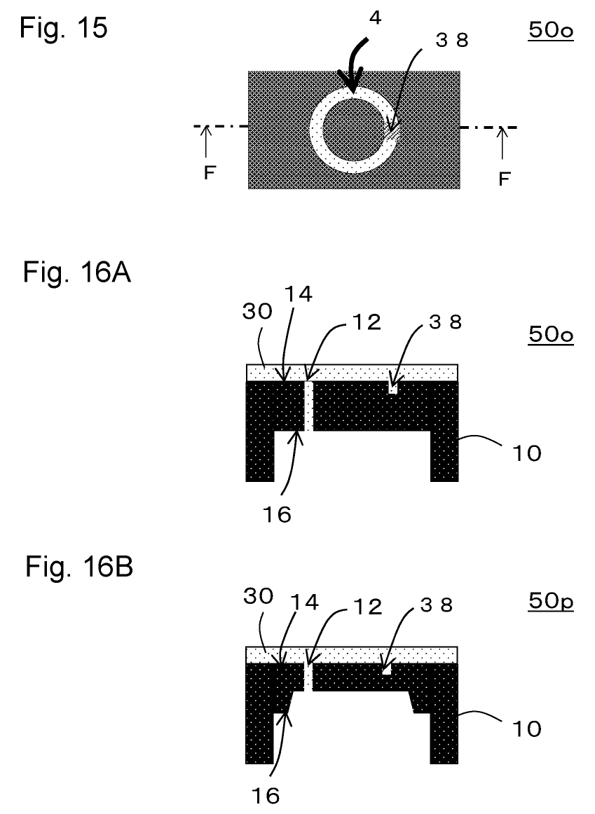

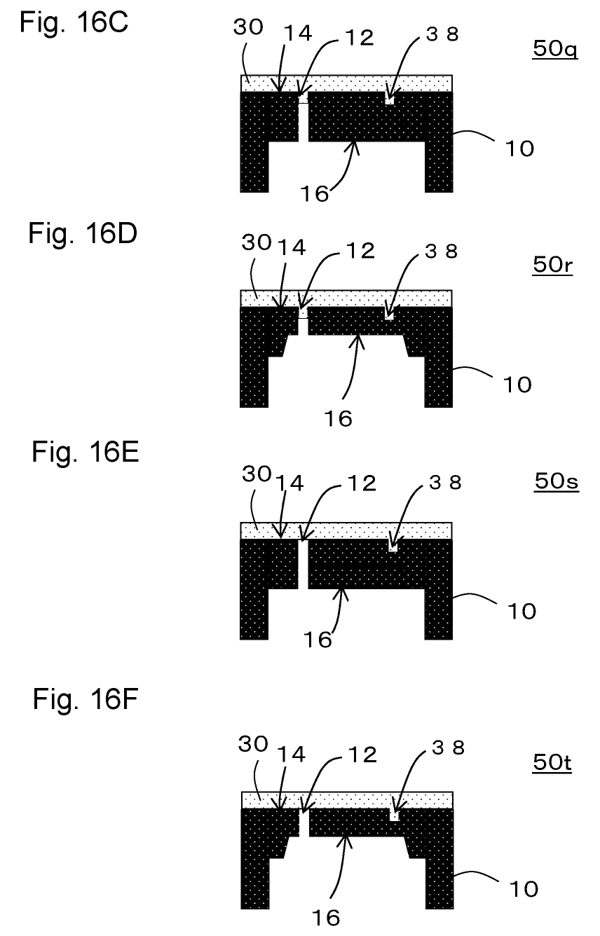

FIG. 15 is a plan view of the resin molded article with a coating film 50o according to a fifth embodiment as viewed from the upper surface side. FIG. 16A is a schematic cross-sectional view taken along line F-F in FIG. 15. FIG. 16B is a schematic cross-sectional view of a resin molded article with a coating film 50p according to a thirteenth modification.

As illustrated in the plan view of FIG. 15, the resin molded article with a coating film 50o according to the fifth embodiment forms a symbol 4 of an alphabet O. As illustrated in FIG. 16A, the symbol 4 includes a through-hole 12 and a bottomed hole 38. In a case of a configuration of a symbol in which the center and the outside are separated, such as O of an alphabet or 0 (zero) of an Arabic numeral, if the whole is configured with a through-hole, the center is separated from the outside and falls. Therefore, the configuration cannot be realized only with the through-hole. Therefore, for example, in FIG. 16A, a part of the through-hole 12 is made into a bottomed hole 38, and an alphabet O is configured as a symbol 4 with a so-called floating island structure including a central island surrounded by the through-hole 12 and a bridge portion connected to the outside by the bottomed hole 38. In this case, for example, by appropriately setting the width of the bridge portion defined by the width of the bottomed hole 38, light from the surrounding through-hole 12 is guided to the upper portion of the bottomed hole 38 when the light is emitted from the lower portion of the through-hole 12, and O of the alphabet can be displayed. This makes it possible to make the bridge portion inconspicuous.

Note that by adjusting the width of the bridge portion, not only O of the alphabet can be displayed as a symbol, but also C of the alphabet can be displayed, for example, by widening the width of the bridge portion.

Note that, in FIG. 16A, the back surface 16 has a single step shape and is flush. In contrast, in the thirteenth modification illustrated in FIG. 16B, the back surface 16 has a multiple step shape having an inner edge portion 17 and an outer edge portion 18.

### Fourteenth to Seventeenth Modifications

FIGS. 16C to 16F are schematic cross-sectional views of resin molded articles with a coating film 50q, 50r, 50s, and 50t according to fourteenth to seventeenth modifications.

In the resin molded article with a coating film 50q according to the fourteenth modification, a part of the through-hole 12 is filled with the coating film 30. Specifically, the thickness is about the same as the thickness of the coating film filled on the bottomed hole 38. The resin molded article with a coating film 50r according to the fifteenth modification is different from the fourteenth modification in that it has a multiple step shape having an inner edge portion 17 and an outer edge portion 18.

In the resin molded article with a coating film 50s according to the sixteenth modification, the through-hole 12 is not filled with the coating film, and the coating film 30 covers one end surface of the through-hole and the front surface of the primary resin molded component around the one end surface of the through-hole. The resin molded article with a coating film 50t according to the seventeenth modification is different from the sixteenth modification in that it has a multiple step shape having an inner edge portion 17 and an outer edge portion 18.

### Thirteenth and Eighteenth Modifications

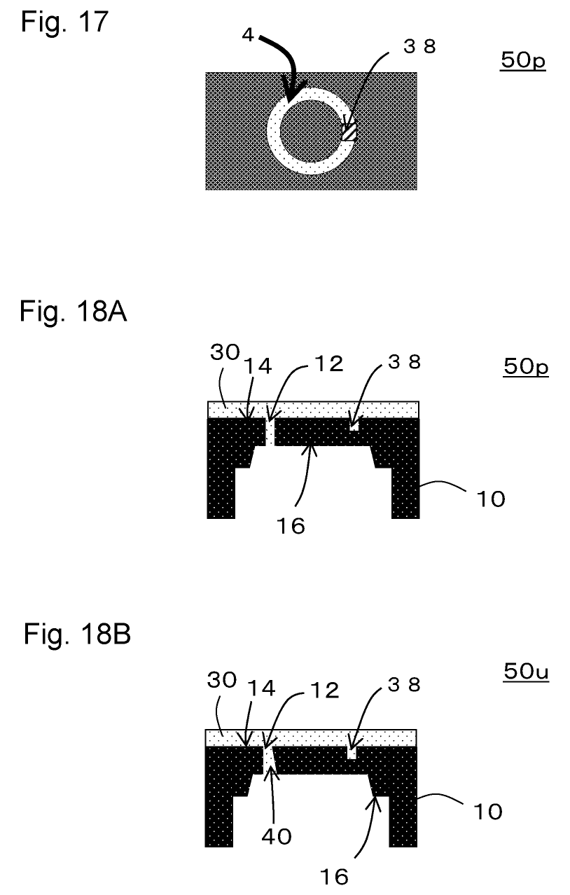

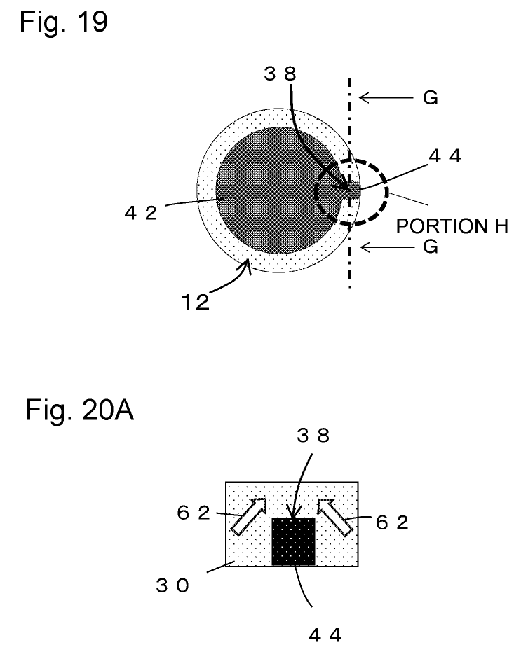

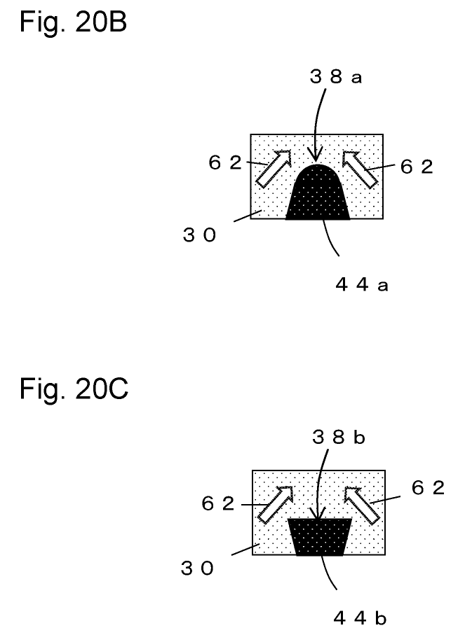

FIG. 17 is a plan view of a resin molded article with a coating film 50p according to a thirteenth modification as viewed from the upper surface side. FIG. 18A is a schematic cross-sectional view of a resin molded article with a coating film 50p according to the thirteenth modification. FIG. 18B is a schematic cross-sectional view of a resin molded article with a coating film 50u according to an eighteenth modification. FIG. 19 is a partial plan view illustrating the island portion 42 at the center, the surrounding through-hole 12, and the bridge portion 44 at the lower portion of the bottomed hole 38 in FIG. 17. FIG. 20A is a schematic cross-sectional view taken along line G-G in FIG. 19 of a portion H including the coating film 30 filling the through-hole and the bridge portion 44 at the lower portion of the bottomed hole 38.

As described above, the resin molded article with a coating film 50p according to the thirteenth modification forms the symbol 4 of the alphabet O as illustrated in the plan view of FIG. 17. The resin molded article with a coating film 50u according to the eighteenth modification is different from the thirteenth modification in that the through-hole 12 has a tapered portion 40 expanding toward the back surface. As a result, the coating film 30 filled in the through-hole 12 is not likely to be removed.

As illustrated in FIG. 20A, when light 62 is emitted from the lower portion of the through-hole, the light 62 travels around the upper portion of the bottomed hole 38 from the coating film 30 filling the through-hole and escapes to the surface, and the symbol 4 of the alphabet O can be visually recognized on the surface. In addition, in the resin molded article with a coating film 50u according to the eighteenth modification, since the through-hole 12 has the tapered portion 40 expanding downward, light from the lower portion is more likely to be guided.

### Nineteenth and Twentieth Modifications

FIG. 20B is a schematic cross-sectional view of a portion H of the resin molded article with a coating film according to a nineteenth modification, the portion H including the coating film 30 filling the through-hole and the bridge portion 44a at the lower portion of the bottomed hole 38a. FIG. 20C is a schematic cross-sectional view of a portion H of the resin molded article with a coating film according to a twentieth modification, the portion H including the coating film 30 filling the through-hole and the bridge portion 44b at the lower portion of the bottomed hole 38b.

In the resin molded article with a coating film according to the nineteenth modification, the bridge portion 44a has a tapered shape in which the upper portion is thin. This causes light to be likely to be guided from the lower portion to the upper portion. In addition, this causes the coating material to be likely to flow during manufacturing.

In the resin molded article with a coating film according to the twentieth modification, the bridge portion 44b has a tapered shape in which the upper portion is thick. This makes it difficult for the coating film to come off.

### Twenty First and Twenty Second Modifications

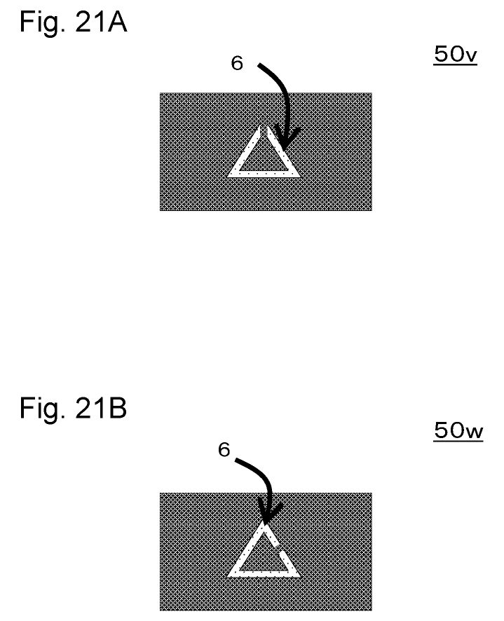

FIG. 21A is a plan view of a resin molded article with a coating film 50v according to a twenty first modification as viewed from the upper surface side. FIG. 21B is a plan view of a resin molded article with a coating film 50w according to a twenty second modification as viewed from the upper surface side.

As illustrated in the plan view of FIG. 21, the resin molded article with a coating film 50v according to the twenty first modification forms a triangular symbol 6. In the twenty first modification, a bridge portion is provided at a vertex of the triangle. Also in this case, configuration has the floating island structure similarly to the fifth embodiment and the thirteenth to twentieth modifications. The resin molded article with a coating film 50w according to the twenty second modification is different from the twenty first modification in that a bridge portion is provided at a portion of a side of the triangle.

The resin molded article with a coating film according to the present disclosure has a high decoration quality and is capable of high-definition optical display when used in an optical device. In contrast, the resin molded article has a concealing property that a symbol or the like cannot be seen through other than during use.

### REFERENCE SIGNS LIST

2 Symbol (C)

4 Symbol (O)

6 Symbol (triangular symbol)

10 Primary resin molded component

12 Through-hole

14 Front surface

16 Back surface

17 Inner edge portion

18, 18a, 18b Outer edge portion

19 Protrusion

22 Grain

30 Coating film

32 Undercut portion

34 Vacant space

36 Catching portion

38 Bottomed hole

40 Tapered portion

42 Island portion

44 Bridge portion

50 Resin molded article with a coating film

52 Substrate (shielding portion)

54 Dark room

60 LED (light irradiation unit)

60a Optical fiber

62 Light

70 Mold for a resin molded article

72 First core mold

74 Cavity mold for a resin molded article

76 Cavity for a resin molded article

77 Recess

78 Resin injection gate

79 Runner gate

80 Mold for coating film

82 Second core mold

84 Cavity mold for a coating film

86 Cavity for a coating film

88 Coating material injection head

100 Optical device

What is claimed is:

1. A resin molded article with a coating film, comprising:
a primary resin molded component having a through-hole; and
an optically transparent coating film covering one end surface of the through-hole of the primary resin molded component and a front surface of the primary resin molded component around the one end surface of the through-hole.

2. The resin molded article with a coating film according to claim 1, wherein the coating film fills a part of the through-hole.

3. The resin molded article with a coating film according to claim 1, wherein the coating film covers from the one end surface of the through-hole to a part of an inner wall of the through-hole.

4. The resin molded article with a coating film according to claim 1, wherein the coating film is filled from the one end surface to another end surface of the through-hole.

5. The resin molded article with a coating film according to claim 4, wherein the coating film has an undercut portion that wraps around from a circumference of another end surface of the through-hole to a part of a back surface of the primary resin molded component.

6. The resin molded article with a coating film according to claim 1, wherein the through-hole is formed by a vacant space extending from the one end surface to another end surface.

7. The resin molded article with a coating film according to claim 1, wherein the coating film contains at least one selected from a group including a filler, a pigment, and a dye.

8. The resin molded article with a coating film according to claim 1, wherein, in a back surface of the primary resin molded component, a thickness of an inner edge portion around another end surface of the through-hole is thinner than a thickness of an outer edge portion radially outer around the inner edge portion.

9. The resin molded article with a coating film according to claim 1, wherein the primary resin molded component has a thickness changing portion on a back surface, wherein the thickness increases from an inner side toward an outer side in a radial direction around the through-hole.

10. The resin molded article with a coating film according to claim 1, wherein the through-hole has an uneven shape, a grain shape, or a tapered shape on an inner surface of the through-hole, and the primary resin and the coating film are meshed and joined via the uneven shape, the grain shape, or the tapered shape.

11. The resin molded article with a coating film according to claim 1, wherein the coating film has a surface having an uneven shape or a grain shape.

12. The resin molded article with a coating film according to claim 1, wherein the coating film is a cured coating material.

13. The resin molded article with a coating film according to claim 1, wherein the coating film extends from the one end surface of the through-hole to a front surface of the primary resin molded component, and has an undercut portion wrapping around from an end portion of the front surface to a back surface of the primary resin molded component.

14. An optical device, comprising:
the resin molded article with a coating film according to claim 1;
a shielding portion covering a circumference of another end surface of the through-hole and forming a dark room with a back surface of the resin molded article; and
a light irradiation unit configured to irradiate from inside the dark room formed between the back surface of the resin molded article and the shielding portion to another end surface of the through-hole with light.

15. A method for manufacturing a resin molded article with a coating film, the method comprising:
preparing a primary resin molded component having a through-hole; and
covering one end surface of the through-hole of the primary resin molded component and a front surface of the primary resin molded component around the one end surface of the through-hole with an optically transparent coating film to obtain a resin molded article with a coating film including the primary resin molded component and the coating film.

16. The method for manufacturing a resin molded article with a coating film according to claim 15,
wherein preparing a primary resin molded component having a through-hole includes:
clamping a first core mold and a cavity mold for a resin molded article of a mold for a resin molded article together, and defining a cavity for a resin molded article corresponding to the primary resin molded component having the through-hole;
introducing a primary resin into the cavity for a resin molded article to form the primary resin molded component having the through-hole; and
opening the first core mold and the cavity mold for a resin molded article to obtain the primary resin molded component having the through-hole.

17. The method for manufacturing a resin molded article with a coating film according to claim 15,
wherein preparing a primary resin molded component having a through-hole is cutting a primary resin material obtained by molding a primary resin into an optional shape, to obtain the primary resin molded component having the through-hole.

18. The method for manufacturing a resin molded article with a coating film according to claim 15,
wherein preparing a primary resin molded component having a through-hole is forming a primary resin molded component by shaping with a 3D printer.

19. The method for manufacturing a resin molded article with a coating film according to claim 15,
wherein covering one end surface of the through-hole of the primary resin molded component and a front surface of the primary resin molded component around the one end surface of the through-hole with an optically transparent coating film includes:
placing the primary resin molded component having the through-hole, on a second core mold, and clamping the second core mold and a cavity mold for a coating film together to define a cavity for a coating film, the cavity including the one end surface of the through-hole;
filling the cavity for a coating film with an optically transparent coating material to form a coating film, the coating film, with the coating material, covering the one end surface of the through-hole and a front surface of the primary resin molded component around the one end surface of the through-hole; and
opening the second core mold and the cavity mold for a coating film and pushing out a resin molded article with a coating film having the coating film from inside the second core mold to obtain the resin molded article with a coating film.

20. The method for manufacturing a resin molded article with a coating film according to claim 19, wherein, in the course of filling for the cavity, the through-hole is filled with the coating material.

21. The method for manufacturing a resin molded article with a coating film according to claim 19,
wherein the second core mold is provided with a recess that introduces the coating material to a back surface of the through-hole of the primary resin molded component, the back surface facing the second core mold, and
in the course of filling for the cavity, the coating material is introduced from a front surface facing the cavity mold for a coating film to the back surface, to form a wraparound portion extending from one end surface of the through-hole through the front surface of the primary resin molded component and wrapping around from an end portion of the front surface to the back surface of the primary resin molded component.
